(19) United States
(12) Patent Application Publication
(10) Pub. No.: US 2005/0258280 A1
(43) Pub. Date: Nov. 24, 2005

(54) Shower plate for plasma processing apparatus and plasma processing apparatus

(75) Inventors: Keiichi Goto, Gunma (JP); Makoto Kawai, Gunma (JP); Kenji Satoh, Gunma (JP)

Correspondence Address: OLIFF & BERRIDGE, PLC, P.O. BOX 19928, ALEXANDRIA, VA, 22320, US

(73) Assignee: SHIN-ETSU CHEMICAL CO., LTD., Chiyoda-ku (JP)

(21) Appl. No.: 11/118,373

(22) Filed: May 2, 2005

(30) Foreign Application Priority Data
May 24, 2004 (JP) 2004-153141

(51) Int. Cl. B05B 3/04

(52) U.S. Cl. 239/548; 239/600

(57) ABSTRACT

There is disclosed a shower plate 1, wherein the shower plate has a plurality of holes 3 for inserting the head of the fastening member and holes 4 for fitting the head are formed integrally along a concentric circle in the outside region of the gas feeding holes 2 on a side facing the supporting member, each hole for fitting extending in one direction of the concentric circle from each hole for insertion, each hole for fitting has a groove portion 4b through which the shank of the fastening member is to pass and a fitting portion 4a which is wider than the groove portion and in which the head of the fastening member is to be fitted, and the head of the fastening member fixed in the supporting member is inserted into the hole for insertion of the shower plate and the shower plate is turned so that the head of the fastening member is fitted in the fitting portion, and thereby the shower plate is supported by the supporting member without exposure of the fastening member. There can be provided a shower plate for a plasma processing apparatus, wherein effective diameter is large enough, contamination of a substrate to be treated can be prevented, it is easy to manufacture, and it is easy to fix to a supporting member.

### BACKGROUND OF THE INVENTION

1. Field of the Invention

The present invention relates to a shower plate for a plasma processing apparatus and a plasma processing apparatus used for dry plasma etching of a substrate such as a semiconductor wafer.

2. Description of the Related Art

As one of apparatuses for fabricating a semiconductor device, a parallel plate plasma processing apparatus represented by a plasma dry etching apparatus is conventionally used. As shown in FIG. 4, for example, in a chamber 26 of plasma processing apparatus 20, an upper electrode unit 24 is disposed opposite a lower electrode 23.

The upper electrode unit 24 is mainly composed of a supporting member 21 and a shower plate 22 which are made of aluminum and the like. Many through-holes (gas feeding holes) 25 for feeding reaction gas are formed in the shower plate 22 and holes (not shown) for fixing the shower plate 22 to the supporting member 21 are formed in the outside region of the gas feeding holes to penetrate the shower plate 22. And when setting up the upper electrode unit 24, for example, anodized aluminum screws are inserted to the holes for fixing the shower plate 22 from the side facing a substrate to be treated 27 (a silicon wafer, etc.) and are fastened, so that the shower plate 22 is fixed to the supporting member 21.

When processing the wafer 27, the upper electrode unit 24 is connected to a high frequency power supply (not shown), and gas for processing is guided and fed toward the wafer through the gas feeding holes 25 of the shower plate 22, thereby plasma is generated between the shower plate 22 and the wafer 27, and the wafer 27 can be subjected to the desired etching.

Furthermore, a focus ring 28 for processing the wafer 27 uniformly is disposed at the periphery of the lower electrode 23.

In such a plasma dry etching apparatus 20, since plasma is generated between the wafer 27 and the shower plate 22 to perform etching process, the shower plate 22 as well as the wafer 27 is essentially etched, so that there is a problem that particles and contamination are caused. Especially, according to the recent higher and finer integration of the semiconductor device, a shower plate 22 with far better performance and quality is required.

Then, to reduce generation of such contamination and the like, a shower plate made of silicon that is the same material as the silicon wafer to be treated attracts attention, instead of the conventional shower plate made of carbon or aluminum. In the case that a shower plate is made of silicon, contamination is drastically reduced even if the shower plate is etched. Therefore, an adverse effect on device caused by the shower plate itself is reduced, and yield and productivity can be improved.

However, even if the shower plate made of silicon is used, said screws for fixing the shower plate are exposed on the side facing the wafer, which becomes a source of generation of the contamination.

In this connection, to prevent generation of the contamination more effectively, it is suggested to mount a cover ring 29 as shown in FIG. 5. Namely, as shown in FIG. 6, after a screw 30 is inserted to a hole for fixing 31 of the shower plate 22 to fix the shower plate 22 to the supporting member 21, the cover ring 29 for covering the exposed portion of the screw 30 (head 30a) is mounted. Thereby the screw 30 is not exposed to plasma, and contamination is prevented more effectively.

However, if the above cover ring 29 is mounted, an accessory inessential for plasma processing itself is added, and there needs further step to fix the accessory, so that it leads to cost increase and efficiency reduction. Furthermore, because the gas feeding holes cannot function in the outside region covered by the cover ring 29, there is a drawback that the effective diameter of the shower plate 22 substantially becomes smaller.

Then, as disclosed in Japanese patent application laid open (Kokai) No. 2003-297806, it is suggested that, blind holes are formed in the outside region of a side facing a supporting member of a shower plate, a socket made of synthetic resin and the like and having threaded holes is inserted to the blind hole, and further, a screw is fastened in the threaded hole of the socket from the side of the supporting member, thereby fixing the shower plate. The shower plate thus fixed to the supporting member has no exposed screws, and no cover ring is required.

However, structures of the sockets and the holes for inserting the sockets are complicated, and therefore production cost increases. Furthermore each hole of the supporting member for fixing the shower plate are necessary to correspond precisely to each hole formed in the sockets. It is difficult to work with checking the correspondence. Thus there is a problem that the work to fix the shower plate to the supporting member is complicated.

### SUMMARY OF THE INVENTION

The present invention has been accomplished to solve the above-mentioned problems, and a main object of the present invention is to provide a shower plate for a plasma processing apparatus that an effective diameter is large enough, contamination of the substrate to be treated can be prevented, it is easy to manufacture, and it is easy to fix to the supporting member.

To achieve the above object, the present invention provides a shower plate to be supported through fastening member whose a diameter of head is larger than that of its shank by a supporting member positioned opposite a substrate to be treated in a plasma processing apparatus,
wherein the shower plate has through-holes for feeding gas,
a plurality of holes for inserting the head of the fastening member and holes for fitting the head are formed integrally along a concentric circle in the outside region of the gas feeding holes on a side facing the supporting member, each hole for fitting extending in one direction of the concentric circle from each hole for insertion,
each hole for fitting has a groove portion through which the shank of the fastening member is to pass and a fitting portion which is wider than the groove portion and in which the head of the fastening member is to be fitted, and
the head of the fastening member fixed in the supporting member is inserted into the hole for insertion of the shower plate and the shower plate is turned so that the head of the fastening member is fitted in the fitting portion, and thereby the shower plate is supported by the supporting member without exposure of the fastening member.

The shower plate having such a structure is easy to manufacture. Furthermore, the shower plate is easy to put on and taken off by just turning it with respect to the supporting member without auxiliary parts like the socket, so that it is excellent in workability. In addition, a cover ring is not necessary and the effective diameter is large enough. And because the fastening member like screws and so on are not exposed, contamination of a substrate to be treated like a wafer and so on can be prevented effectively.

In that case, the width of the fitting portion is preferably formed larger than that of the groove portion by the range of 1-20 mm.

As described above, when the width of the fitting portion is formed larger than that of the groove portion by the range of 1-20 mm, it is very easy to manufacture, and holding power to fix the shower plate is obtained enough, so that the shower plate is fixed securely.

Furthermore, the shower plate preferably has a diameter in the range of 300-500 mm, and a thickness in the range of 5-30 mm.

If the shower plate has the above size, its material is easily available, and the holes are also easily formed. Furthermore, because a silicon wafer being a typical substrate to be treated has mainly a diameter in the range of 200-300 mm, the whole of a wafer can be processed uniformly by using the shower plate having the above size.

Furthermore, the present invention provides a plasma processing apparatus provided with the shower plate.

As described above, if the plasma processing apparatus is provided with the shower plate according to the present invention, a substrate to be treated like a silicon wafer and so on can be processed without contamination because the fastening member like screw and so on is not exposed. In addition, there's no need for auxiliary parts like cover ring and so on, so that it leads to cost reduction.

As described above, the shower plate according to the present invention can be easily put on and taken off by turning with respect to the supporting member, so that workability is extremely excellent. In addition, there is no need for auxiliary parts like cover ring, socket and so on, so that it leads to cost reduction. And also, the shower plate can be fixed to the supporting member without exposure of the fastening member. Accordingly, contamination of a substrate to be treated can be prevented effectively.

### BRIEF DESCRIPTION OF THE DRAWINGS

FIG. 1 is a schematic plan view of one example of the shower plate according to the present invention.

FIG. 2 is a schematic view of the state that the shower plate according to the present invention is supported by the supporting member.

FIG. 3(A) is an enlarged schematic plan view of the hole for fixing (hole for insertion and hole for fitting).

FIG. 3(B) is an enlarged schematic section view of the hole for fixing.

FIG. 4 is a schematic view of one example of a conventional plasma etching apparatus.

FIG. 5 is a schematic view of one example of a plasma etching apparatus equipped with a cover ring.

FIG. 6 is a schematic view of the procedure of equipping a cover ring.

### DESCRIPTION OF THE INVENTION AND A PREFERRED EMBODIMENT

The shower plate according to the present invention will be further described below in detail referring to the appended drawings.

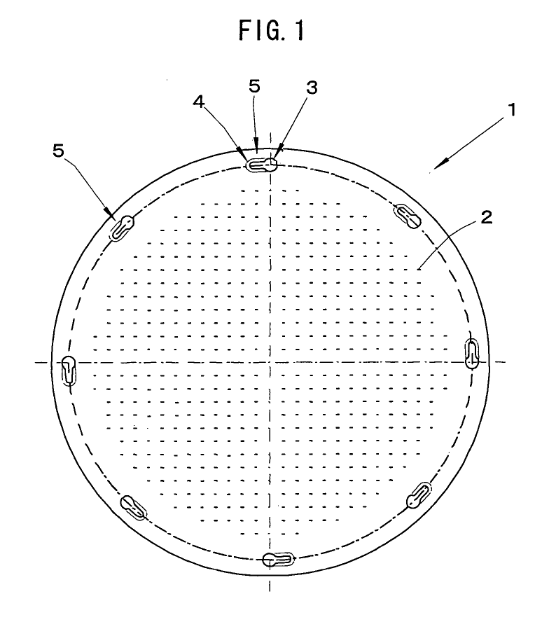

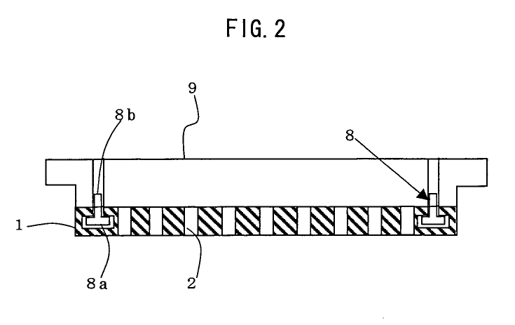

FIG. 1 schematically shows one example of the shower plate according to the present invention. FIG. 2 shows the state that the shower plate 1 is supported through fastening member 8 by a supporting member 9.

As shown in FIG. 1, many fine through-holes for guiding and feeding gas (gas feeding holes) 2 are formed overall the shower plate 1 except outside region (periphery region). Holes 5 for fixing the shower plate 1 through fastening members 8 by the supporting member 9 are formed at 8 places equally spaced along a concentric circle in the outside region of the gas feeding holes 2.

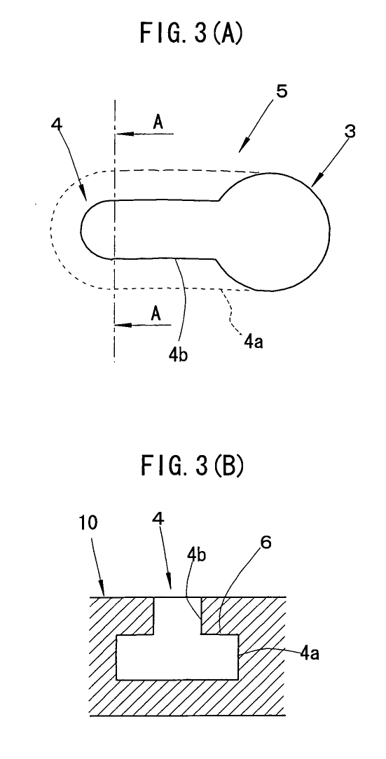

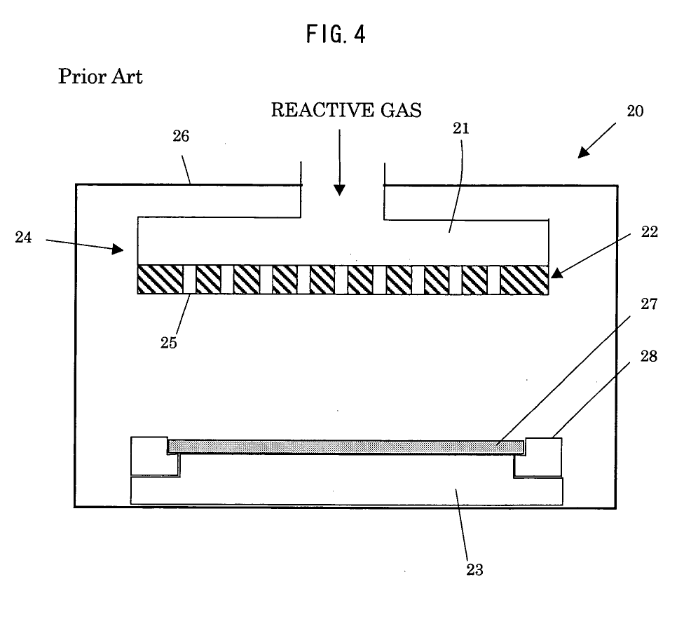

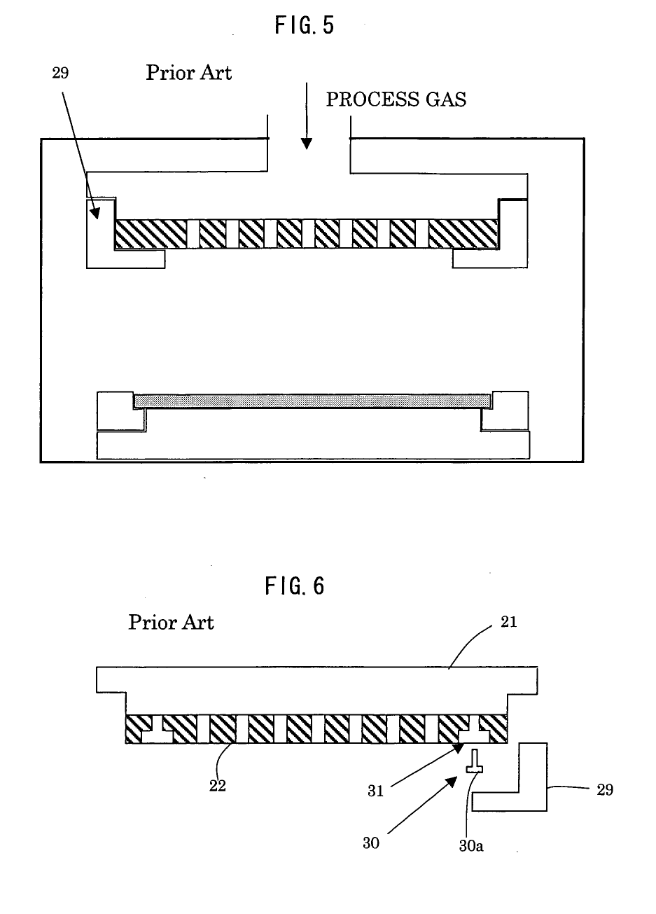

FIGS. 3 (A) and (B) show enlarged detail of the hole for fixing 5. The hole for fixing 5 is formed only on the side 10 facing the supporting member 9 without penetrating to the side facing a substrate to be treated. A hole 3 for inserting the head 8a of the fastening member 8 (e.g. screws, etc.) and a hole 4 for fitting the head 8a which extends in one direction of the concentric circle from the hole for insertion 3, are formed integrally

The hole for insertion 3 is formed in the shape of a circle having the size that the head 8a of the fastening member 8 used can be inserted thereto.

At the same time, as shown in FIG. 3 (B), the hole for fitting 4 has a step 6 formed in the direction of depth. The hole 4 comprises a groove portion 4b through which the shank 8b of the fastening member 8 is to pass and a fitting portion 4a which is more widely formed than the groove portion 4b and into which the head 8a of the fastening member 8 is to be fitted. The hole for fitting 4 doesn't always have to have the step 6 as shown in FIG. 3 (B). For example, the hole 4 may have an inclination that becomes wider from the groove portion 4b (aperture) toward the fitting portion 4a.

Although the method for manufacturing the shower plate 1 is not limited to specific one, for example, it can be easily manufactured according to the procedure as mentioned below.

First of all, a silicon single crystal ingot is cut at a given thickness to form a circular plate. The size of the shower plate (circular plate) may be properly decided depending on the size and the like of a substrate to be treated (wafer), it is preferable that its diameter is in the range of 300-500 mm in view of workability and cost for manufacture. A plate having a size in this range is easily available and also easy to process, so that the manufacturing cost can be lowered. For example, in recent years, a silicon single crystal ingot having a diameter of 300 mm has been mass-produced for silicon wafers by Czochralski method, it is relatively easily available.

In addition, as to thickness of the plate 1, because blind holes 3 and 4 for fixing the plate 1 to the supporting member 9 are formed in the shower plate 1 according to the present invention, it is possibly difficult to form these holes 3 and 4 when the thickness of the plate 1 is less than 5 mm. On the contrary, it is may be difficult to form through-holes as gas feeding holes when the thickness is more than 30 mm. Therefore, it is preferable that thickness of the plate is in the range of 5-30 mm.

In the plate cut out from an ingot as mentioned above, many through-holes 2 having a diameter in the range of 0.5-5 mm, for example, are formed as gas feeding holes 2.

Furthermore, in the outside region of the gas feeding holes 2, the hole 3 for inserting the head 8a of the fastening member 8 is formed by use of a drill with a given diameter and the like. Here, this hole for insertion 3 is formed from the side 10 facing the supporting member and is formed not to penetrate. The size of the hole for insertion 3 can be decided depending on the size of the shower plate, the head of the fastening member and the like, in consideration of the strength of the plate and workability, the hole 3 is preferable in the range of a diameter of 3-30 mm and a depth of 5-20 mm.

Besides, the number of holes for fixing 5 (holes for insertion 3, holes for fitting 4) can be properly decided depending on the size of the plate, and it is not limited to 8 holes as shown in FIG. 1. But, if the number of the holes is too few, a load to each hole becomes too much and possibly destroys the holes. Therefore, in order to support the shower plate 1 stably, it is preferable that the holes for fixing 5 are formed at 3 places or more and at equal spaces.

After plurality of holes for insertion 3 are formed along a concentric circle on the plate, holes for fitting 4 each of which extends from each of the holes for insertion 3 are formed in one direction of the concentric circle, for example, counterclockwise as shown in FIG. 1. Thus the holes 3 and 4 are formed integrally. The procedure to form the holes for fitting 4 is exemplified as follows.

For a start, the groove portion 4b is formed by use of a drill with a given diameter. Then, a tool is prepared, which has a cutting jig in one end and the cutting jig has the same diameter as the holes for insertion 3 and the thickness corresponding to the fitting portion 4a to be formed. After the cutting jig at the end of the tool is inserted to the hole for insertion 3, the cutting jig is moved along the groove portion 4b while rotating the cutting jig. The fitting portion 4a is thus formed at a given depth, and the hole for fitting 4 having the section as shown in FIG. 3(B) and the hole for insert-ion 3 can be formed integrally.

Furthermore, when forming the hole for fitting 4, it is preferable that the width of the fitting portion 4a is formed larger than that of the groove portion 4b by the range of 1-20 mm. If the difference between the width of the fitting portion 4a and that of the groove portion 4b is less than 1 mm, there's a possibility that the head 8a of the fastening member 8 comes away from the fitting portion 4a, and that the processing becomes difficult when the difference is more than 20 mm. Therefore, if the difference is in the above range, the processing is easy and the head 8a of the fastening member 8 is prevented from coming away, so that the shower plate 1 can be supported securely.

As mentioned above, the shower plate 1 wherein the hole 3 for inserting a head of the fastening member like screw and so on and the hole 4 for fitting the head are formed integrally on the outside region, can be fixed easily and securely through the fastening member by the supporting member without auxiliary parts like sockets. The procedure for fixing the shower plate 1 to the supporting member 9 of a plasma processing apparatus will be explained below.

First of all, fastening member 8 whose a diameter of head 8a is larger than that of its shank 8b like screw and so on is prepared. Material of the fastening member 8 is not limited because the shower plate 1 according to the present invention can be fixed to the supporting member 9 without exposure of the fastening member 8. In general, a fastening member made of aluminum or other metal is preferably used. A fastening member made of resin and so on having great strength can also be used. Furthermore, the fastening member 8 of the present invention includes one whose diameter of head is larger than that of its shank like pin or bolt and so on, and it is not limited to screws.

Then, the shank 8b of the fastening member 8 is fixed to the supporting member 9. Here, the whole shank of the fastening member 8 is not sunk into the supporting member, and the shank is fixed to project from the supporting member by approximate length as long as the depth of the groove portion 4b of the shower plate 1 or more.

After each fastening member 8 is fixed to the supporting member 9 at place corresponding to hole for insertion 3 of the shower plate 1, each head 8a of the fastening member 8 is inserted to the hole for insertion 3 of the shower plate 1. Then, as all heads 8a of the fastening members 8 are inserted to the holes for insertion 3, the shower plate 1 is turned opposite to the direction that holes for fitting 4 extend. Here, the shank 8b of the fastening member 8 projecting from the supporting member 9 is passing the groove portion 4b of the hole for fitting 4 and at the same time the head 8a of the fastening member 8 is fitted to the fitting portion 4a. Thereby, as shown in FIG. 2, the shower plate 1 can be easily and securely supported to the supporting member 9 without exposure of the fastening member 8.

In addition, since such a shower plate 1 needs no cover ring, the effective diameter remains large enough. Furthermore, the shower plate 1 needs no auxiliary parts having complex structure like socket, thereby cost is very low.

And when a silicon wafer is subjected to plasma etching by a plasma processing apparatus comprising such the shower plate 1, contamination of the wafer is far reduced even if the shower plate itself is etched and thereby it leads to improving yield and productivity of the semiconductor device and the like.

### EXAMPLE

An example of the present invention will be explained below.

### EXAMPLE

A plate having a diameter of 350 mm and a thickness of 10 mm was prepared from a base material of silicon single crystal ingot.

After through-holes that function as gas feeding holes were formed in the plate along the direction of the thickness, a hole for inserting the fastening member and a hole for fitting it were formed to be one unit on the side facing the supporting member, at 8 places along a concentric circle in the outside region of the gas feeding holes. Here, each hole for insertion was formed as a countersink having a diameter of 10 mm and a depth of 8 mm. On the other hand, each hole for fitting was formed to extend counterclockwise with inclining by 5° along a concentric circle on which the holes for insertion are formed, at the same time a step was formed in the direction of depth so that the hole for fitting may comprise the fitting portion having a diameter of 10 mm and a maximum depth of 8 mm, and the groove portion (aperture) having a width of 5 mm and a maximum depth of 4 mm.

As fastening member, 8 screws made of aluminum were prepared. The head of the screw has a diameter of about 10 mm and a height of 4 mm, and the shank of it has a diameter of about 5 mm and a length of 20 mm.

The shanks of these screws were fixed to a supporting member made of aluminum, at places corresponding to holes for insertion on the shower plate, with exposing the shank from the supporting member by about 4 mm. The each hole of the shower plate was formed to have a play for the fastening member fixed to the supporting member.

Then, heads of the screws fixed to the supporting member were inserted to the holes for insertion, respectively, and the shower plate was turned counterclockwise as viewed from a side facing a substrate to be treated. Thereby, each head of the screws is fitted to the hole for fitting, so that the shower plate could be easily supported by the supporting member.

A silicon wafer having a diameter of 300 mm was subjected to plasma treatment by use of a plasma processing apparatus with feeding gas including CF₄′ so that the silicon wafer was not contaminated and could be processed without problems.

The present invention is not limited to the above-described embodiments. The above-described embodiments are mere examples, and those having the substantially same structure as that described in the appended claims and providing the similar action and effects are included in the scope of the present invention.

The shower plate according to the present invention is not limited to being used for plasma etching of a silicon wafer. For example, material of the shower plate can be properly selected depending on a substrate to be treated, like the same material as the substrate or the material that doesn't contaminate the substrate.

1. A shower plate to be supported through fastening member whose a diameter of head is larger than that of its shank by a supporting member positioned opposite a substrate to be treated in a plasma processing apparatus,
wherein the shower plate has through-holes for feeding gas,
a plurality of holes for inserting the head of the fastening member and holes for fitting the head are formed integrally along a concentric circle in the outside region of the gas feeding holes on a side facing the supporting member, each hole for fitting extending in one direction of the concentric circle from each hole for insertion,
each hole for fitting has a groove portion through which the shank of the fastening member is to pass and a fitting portion which is wider than the groove portion and in which the head of the fastening member is to be fitted, and
the head of the fastening member fixed in the supporting member is inserted into the hole for insertion of the shower plate and the shower plate is turned so that the head of the fastening member is fitted in the fitting portion, and thereby the shower plate is supported by the supporting member without exposure of the fastening member.

2. The shower plate according to claim 1, the width of the fitting portion is formed larger than that of the groove portion by the range of 1-20 mm.

3. The shower plate according to claim 1, its diameter is in the range of 300-500 mm, and its thickness is in the range of 5-30 mm.

4. The shower plate according to claim 2, its diameter is in the range of 300-500 mm, and its thickness is in the range of 5-30 mm.

5. A plasma processing apparatus being provided with the shower plate according to claim 1.

6. A plasma processing apparatus being provided with the shower plate according to claim 2.

7. A plasma processing apparatus being provided with the shower plate according to claim 3.

8. A plasma processing apparatus being provided with the shower plate according to claim 4.
